(19) United States
(12) Patent Application Publication
(10) Pub. No.: US 2007/0212200 A1
(43) Pub. Date: Sep. 13, 2007

(54) LIFTER AND TARGET OBJECT PROCESSING APPARATUS PROVIDED WITH LIFTER

(75) Inventors: Atsushi Ueda, Amagasaki-shi (JP); Jun Yamashita, Amagasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/683,015

(22) Filed: Mar. 7, 2007

(30) Foreign Application Priority Data
Mar. 9, 2006 (JP) 2006-064410
Mar. 15, 2006 (JP) 2006-071670

(51) Int. Cl. H01L 21/677

(52) U.S. Cl. 414/217; 438/951

(57) ABSTRACT

Each pin fixing portion is fitted in a through-hole formed in a lifter arm, and includes a flange portion, a movable portion, a screw portion, and a pin insertion hole. A pin is fixedly screwed into the pin insertion hole at a lower end. The movable portion is inserted with an allowance in the through-hole, and the flange portion is set in contact with an upper surface of the lifter arm. The screw portion projects downward from the through-hole. A lower support portion is screwed on the screw portion and set in contact with a lower surface of the lifter arm.

### BACKGROUND OF THE INVENTION

1. Field of the Invention

The present invention relates to a lifter configured to move up and down a target object, such as a semiconductor substrate or a glass substrate for liquid crystal displays, and a processing apparatus provided with such a lifter and arranged to perform a process, such as a film formation, etching, heating, reformation, or crystallization process, on a target object.

2. Description of the Related Art

In manufacturing semiconductor integrated circuits, various processes, such as film formation, etching, heating, reformation, and crystallization processes, are repeatedly performed on a target object, such as a semiconductor wafer, to form integrated circuits on the target object. In each of the steps of a manufacturing process of this kind, a semiconductor wafer is typically placed on a substrate seat member located inside a chamber of a processing apparatus, and then one of various processes is performed on the semiconductor wafer placed on the substrate seat member. In this processing apparatus, a lifter is disposed to move up and down the semiconductor wafer relative to the substrate seat member, when the semiconductor wafer is transferred to and from the substrate seat member.

FIG. 1 is a sectional view showing one of pins and a lifter arm used in a conventional lifter, in which a reference symbol 130 denotes a pin. A substrate table 131 has pin insertion holes 131a formed therethrough in the vertical direction. Each of the pin insertion holes 131a has a shoulder portion 131b on the upper side, so that the upper portion thereabove has a larger diameter than the lower portion therebelow.

The pin 130 includes a head portion 130a at the upper end, which has a larger diameter than the others, and is held on the shoulder portion 131b. The pin 130 is provided with an abutting portion 130b screwed thereon at the lower end, so that the abutting portion 130b is to be in contact with a lifter arm 132.

The lifter arm 132 is located below the substrate table 131 inside the chamber, and is arranged to be moved up and down by a drive shaft (not shown), which penetrates the bottom of the chamber and is movable up and down. When the lifter arm 132 is moved up, the lifter arm 132 comes into contact with the abutting portion 130b of each of the pins 130. Consequently, the pins 130 are moved up along with semiconductor wafer W supported on the head portions 130a of the pins 130. On the other hand, when the lifter arm 132 is moved down, the head portions 130a are held on the shoulder portions 131b while the abutting portions 130b are separated from the lifter arm, so that the semiconductor wafer W is placed on the substrate table 131.

FIG. 2 is a sectional view showing one of pins and a lifter arm used in another conventional lifter, in which a reference symbol 143 denotes a pin. The pin 143 is pressed into or fixedly screwed into a fixing portion 144 at the lower end. The fixing portion 144 includes an upper portion with a larger diameter than a lower portion. A lifter arm 142 has fitting holes 142a. The fixing portion 144 is provided with a washer 145 and a nut 146 disposed thereon. The lower portion of the fixing portion 144 is inserted into the corresponding one of the fitting holes 142a, and the nut 146 is fastened through the washer 145 onto the upper surface of the lifter arm 142, so that the fixing portion 144 is attached.

Jpn. Pat. Appln. KOKAI Publication No. 2004-343032 discloses an invention relating to a lifting mechanism in which a substrate seat member has pin insertion holes formed therein and each provided with an extension sleeve at the lower end. The extension sleeve projects downward coaxially with the pin insertion hole from the peripheral edge of the lower end. In this Patent Document 1, the lower end of each pin is supported by a pin fixing portion formed on a lifter arm, by means of contact (i.e., the pin is separable from the pin fixing portion), as in the pin 130 shown in FIG. 1. When the lifter arm is moved down, the lower end is separated from the lifter arm.

In the case of the lifter shown in FIG. 1, a problem may arise such that the head portion 130a of the lifter pin 130 sticks to a semiconductor wafer W by an electrostatic force and does not fall toward the lifter arm 132, thereby causing a transfer error of the semiconductor wafer W.

In the case of the lifter shown in FIG. 2, since the fixing portion 144 is completely fixed to the lifter arm 142, the pin 143 cannot move in a radial direction. Accordingly, the diameter of the pin 143 is set to be smaller than that of the pin insertion hole 141a, so that the pin 143 can be moved up and down in the pin insertion hole 141a, even where the pin insertion hole 141a becomes narrower due to thermal expansion of the substrate seat member 141 during a process performed on a semiconductor wafer W. Since the pin 143 is thin, alignment of the pin 143 with the pin insertion hole 141a is difficult in assembling the lifter. For example, a problem may arise such that the pin 143 is inserted in an inclined state into the pin insertion hole 141a of the substrate seat member 141, and damages the pin insertion hole 141a.

Conventionally, in general, a lifter 150 employs a C-shaped lifter arm 153 integrally formed, as shown in FIG. 3. The arm 153 is attached to a holder 154 at a base portion, while its opening portion is positioned opposite to the attached side. Elevating shafts 155 are disposed to extend through the holder 154, and are arranged to be moved up and down by an elevating mechanism (not shown).

When an apparatus is assembled, a cylindrical support portion for supporting a substrate table is attached to the bottom of the substrate table, and a support portion fixing member is attached to the lower end of the support portion, thereby fabricating a unit. Then, the unit is inserted into a chamber from above, and the support portion fixing member is attached to a mount component disposed inside the chamber. In this case, if the inner diameter of the lifter arm 150 is larger than the outer diameter of the support portion fixing member, the support portion fixing member can be attached to the mount component in a state where the lifter arm 150 is attached to the chamber, because the support portion fixing member can be carried through the inside of the lifter arm 150.

However, if the inner diameter of the lifter arm 150 is smaller than the outer diameter of the support portion fixing member, a problem arises such that the support portion fixing member cannot be attached to the mount component in a state where the lifter arm 150 is attached to the chamber, because the support portion fixing member cannot be carried through the inside of the lifter arm 150. Further, there is another problem in that the lifter arm 150 cannot be replaced in a state where the support portion fixing member is attached to the chamber.

It has been proposed to divide the lifter arm. Specifically, if the inner diameter of the lifter arm is larger than the outer diameter of the support portion fixing member, the parts of the lifter arm are set to abut on each other and attached to the chamber. Then, the support portion fixing member is carried through the inside of the lifter arm, and is attached to the mount component.

On the other hand, if the inner diameter of the lifter arm is smaller than the outer diameter of the support portion fixing member, the parts of the lifter arm are placed inside the chamber in the divided state without being set to abut on each other. Then, the support portion fixing member is attached to the mount component, and, thereafter, the parts of the lifter arm are set to abut on each other and attached to the chamber.

However, there is a problem in this case, such that it is very difficult, requires a lot of skill, and takes a long time to attach the lifter arm to the chamber in a state where the support portion fixing member is attached to the mount component. Further, there is another problem in that the lifter arm cannot be replaced in a state where the support portion fixing member is attached to the chamber. Further, there is another problem in that the heights of pins may be disconformable due to a difference in dimensional accuracy of the right and left parts of the lifter arm. This disconformity cannot be adjusted even if the processing apparatus includes an inclination adjusting mechanism for elevating shafts.

### BRIEF SUMMARY OF THE INVENTION

An object of the present invention is to provide a lifter and a target object processing apparatus provided with a lifter, which can bring about at least one of the following advantages. Specifically, when a processing apparatus is assembled, alignment of a pin with a pin insertion hole is easy, and thus the diameter of the pin can be larger to prevent the pin from being damaged. Further, the pin is prevented from sticking to a target object and thus from causing a transfer error of the target object.

Another object of the present invention is to provide a lifter, which can bring about at least one of the following advantages. Specifically, a table fixing member fixed to the table can be easily carried through a lifter arm and attached to a chamber. The lifter arm can be replaced in a state where the table fixing member is attached to the chamber. Further, the heights of pins can be adjusted for respective lifter arm parts.

Another object of the present invention is to provide a target object processing apparatus provided with a lifter, which can bring about at least one of the following advantages. Specifically, a table fixing member fixed to the table can be easily carried through a lifter arm and attached to a chamber. The lifter arm can be replaced in a state where the table fixing member is attached to the chamber. Further, the heights of pins can be adjusted for respective lifter arm parts.

According to an aspect of the present invention, there is provided a lifter comprising:

a plurality of pins inserted in a plurality of holes formed through a table for placing thereon a target object to be processed, the plurality of pins being configured to support;

a lifter arm configured to support the plurality of pins; and

pin fixing portions configured to respectively fix the pins to the lifter arm,

such that the pins are moved up and down by the lifter arm and thereby caused to project and retreat relative to the holes of the table so as to move up and down the target object,

wherein each of the pin fixing portions is inserted into a through-hole formed in the lifter arm, and comprises

a movable portion having a pin insertion hole formed therein to fix a corresponding one of the pins, the movable portion being inserted in the through-hole with a gap formed therebetween,

a support portion connected to the movable portion on an upper side and having a diameter larger than that of the movable portion, the support portion being set in contact with an upper surface of the lifter arm while said one of the pins extending therethrough,

an engage portion connected to the movable portion on a lower side and projecting downward from the through-hole, and

a contact portion engaged with engage portion and set in contact with a lower surface of the lifter arm,

such that the pin fixing portion is allowed to move in a horizontal direction by the gap around the movable portion.

According to an alternative aspect of the present invention, there is provided a lifter comprising:

a plurality of pins inserted in a plurality of holes formed through a table for placing thereon a target object to be processed, the plurality of pins being configured to support;

a lifter arm configured to support and move up and down the plurality of pins; and

pin fixing portions configured to respectively fix the pins to the lifter arm,

such that the pins are moved up and down by the lifter arm and thereby caused to project and retreat relative to the holes of the table so as to move up and down the target object,

wherein each of the pin fixing portions is inserted into a screw hole formed in the lifter arm and having a screw on an inner wall, and comprises

a movable portion having a pin insertion hole formed therein to fix a corresponding one of the pins, the movable portion being inserted in the screw hole with a gap formed therebetween,

a support portion connected to the movable portion on an upper side and having a diameter larger than that of the movable portion, the support portion being set in contact with an upper surface of the lifter arm while said one of the pins extending therethrough, and

a stopper portion connected to the movable portion on a lower side and having a male screw formed on an outer surface to be screwed into the screw hole, the stopper portion supporting the movable portion from below while the male screw being screwed into the screw hole and projecting downward from the screw hole,

such that the pin fixing portion is allowed to move in a horizontal direction by the gap around the movable portion.

According to a further alternative aspect of the present invention, there is provided a processing apparatus comprising:

a chamber configured to accommodate a target object;

a table configured to place thereon the target object inside the chamber;

a process mechanism configured to perform a predetermined process on the target object inside the chamber;

a lifter configured to move up and down the target object above the table; and

a driving mechanism for driving the lifter,

wherein the lifter comprises a plurality of pins configured to support and move up and down the target object above the table, a lifter arm configured to support and move up and down the plurality of pins, and pin fixing portions configured to respectively fix the pins to the lifter arm,

the table has a plurality of holes formed therethrough in which the pins are inserted, such that the pins are moved up and down by the lifter arm and thereby caused to project and retreat relative to the holes so as to move up and down the target object, and

each of the pin fixing portions is inserted into a through-hole formed in the lifter arm, and comprises

a movable portion having a pin insertion hole formed therein to fix a corresponding one of the pins, the movable portion being inserted in the through-hole with a gap formed therebetween,

a support portion connected to the movable portion on an upper side and having a diameter larger than that of the movable portion, the support portion being set in contact with an upper surface of the lifter arm while said one of the pins extending therethrough,

an engage portion connected to the movable portion on a lower side and projecting downward from the through-hole, and

a contact portion engaged with engage portion and set in contact with a lower surface of the lifter arm,

such that the pin fixing portion is allowed to move in a horizontal direction by the gap around the movable portion.

According to a further alternative aspect of the present invention, there is provided a processing apparatus comprising:

a chamber configured to accommodate a target object:

a table configured to place thereon the target object inside the chamber;

a process mechanism configured to perform a predetermined process on the target object inside the chamber;

a lifter configured to move up and down the target object above the table; and

a driving mechanism for driving the lifter,

wherein the lifter comprises a plurality of pins configured to support and move up and down the target object above the table, a lifter arm configured to support and move up and down the plurality of pins, and pin fixing portions configured to respectively fix the pins to the lifter arm,

the table has a plurality of holes formed therethrough in which the pins are inserted, such that the pins are moved up and down by the lifter arm and thereby caused to project and retreat relative to the holes so as to move up and down the target object, and

each of the pin fixing portions is inserted into a screw hole formed in the lifter arm and having a screw on an inner wall, and comprises

a movable portion having a pin insertion hole formed therein to fix a lower end of a corresponding one of the pins, the movable portion being inserted in the screw hole with a gap formed therebetween,

a support portion formed as a flange connected to the movable portion on an upper side and having a diameter larger than that of the movable portion, the support portion being set in contact with an upper surface of the lifter arm while said one of the pins extending therethrough, and

a lower support portion connected to the movable portion on a lower side and having a male screw formed on an outer surface to be screwed into the screw hole, the lower support portion supporting the movable portion from below while the male screw being screwed into the screw hole and projecting downward from the screw hole,

such that the pin fixing portion is allowed to move in a horizontal direction by the gap around the movable portion.

According to a further alternative aspect of the present invention, there is provided a lifter comprising:

a plurality of pins inserted in a plurality of holes formed through a table for placing thereon a target object to be processed, the plurality of pins being configured to support;

a lifter arm configured to support the plurality of pins;

a support portion configured to horizontally support the lifter arm; and

an elevating section coupled to the support portion and configured to move up and down while horizontally supporting the lifter arm so as to move up and down the lifter arm,

such that the pins are supported and moved up and down by the lifter arm and thereby caused to project and retreat relative to the holes of the table so as to move up and down the target object,

wherein the lifter arm comprises a pair of arm parts,

the support portion comprises a pair of support plates configured to respectively and horizontally support the arm parts,

the elevating section comprises a pair of elevating shafts respectively coupled to the support plates and configured to move up and down while respectively and horizontally supporting the arm parts so as to move up and down the arm parts, and

the arm parts are operated to move up and down in set positions where the arm parts are close to each other, and the arm parts are separable from each other by rotating the elevating shafts or rotating the support plates relative to the elevating shafts from the set positions.

This lifter may be arranged such that the arm parts respectively extend from ends of the support plates in a direction perpendicular to a longitudinal direction of the support plates, and other ends of the support plates are respectively fixed to upper ends of the elevating shafts by fixing screws extending therethrough,

the lifter further comprises a coupling plate configured to couple the support plates to each other in a state where ends of the support plates are set to abut on each other, and

coupling by the coupling plate is unlocked, and the fixing screws are loosened, so that the support plates are set to be rotatable relative to the elevating shafts, when the arm parts are separated from each other.

According to a further alternative aspect of the present invention, there is provided a processing apparatus comprising:

a chamber configured to accommodate a target object;

a table configured to place thereon the target object inside the chamber;

a process mechanism configured to perform a predetermined process on the target object inside the chamber;

a lifter configured to move up and down the target object above the table; and

a driving mechanism for driving the lifter,

wherein the lifter comprises a plurality of pins configured to support, a lifter arm configured to support the plurality of pins, a support portion configured to horizontally support the lifter arm, and an elevating section coupled to the support portion and configured to move up and down while horizontally supporting the lifter arm so as to move up and down the lifter arm,

the table has a plurality of holes formed therethrough in which the pins are inserted, such that the pins are moved up and down by the lifter arm and thereby caused to project and retreat relative to the holes so as to move up and down the target object,

the lifter arm comprises a pair of arm parts,

the support portion comprises a pair of support plates configured to respectively and horizontally support the arm parts,

the elevating section comprises a pair of elevating shafts respectively coupled to the support plates and configured to move up and down while respectively and horizontally supporting the arm parts so as to move up and down the arm parts, and

the arm parts are operated to move up and down in set positions where the arm parts are close to each other, and the arm parts are separable from each other by rotating the elevating shafts or rotating the support plates relative to the elevating shafts from the set positions.

This processing apparatus may be arranged such that the arm parts respectively extend from ends of the support plates in a direction perpendicular to a longitudinal direction of the support plates, and other ends of the support plates are respectively fixed to upper ends of the elevating shafts by fixing screws extending therethrough,

the lifter further comprises a coupling plate configured to couple the support plates to each other in a state where ends of the support plates are set to abut on each other, and

coupling by the coupling plate is unlocked, and the fixing screws are loosened, so that the support plates are set to be rotatable relative to the elevating shafts, when the arm parts are separated from each other.

### BRIEF DESCRIPTION OF THE SEVERAL VIEWS OF THE DRAWING

FIGS. 1 and 2 are sectional views each showing one of pins and a lifter arm used in a conventional lifter;

FIG. 3 is a plan view showing pins and a lifter arm used in a conventional lifter;

FIG. 4 is sectional view showing a plasma processing apparatus of the microwave type provided with a lifter according to the present invention;

FIG. 5 is an exploded perspective view showing a substrate seat member and a support portion used in the plasma processing apparatus of the microwave type shown in FIG. 4;

FIG. 6 is a perspective view showing a lifter according to an embodiment of the present invention;

FIG. 7 is a perspective view of the lifter shown FIG. 6 in a state where the arms thereof are unfurled;

FIG. 8 is a perspective back view of the lifter shown FIG. 6;

FIG. 9 is a sectional view of the lifter shown FIG. 6 in a state where a pin is inserted into a pin insertion hole formed in a substrate seat member; and

FIG. 10 is a sectional view showing another lifter according to another embodiment of the present invention in a state where a pin is inserted into a pin insertion hole formed in a substrate seat member.

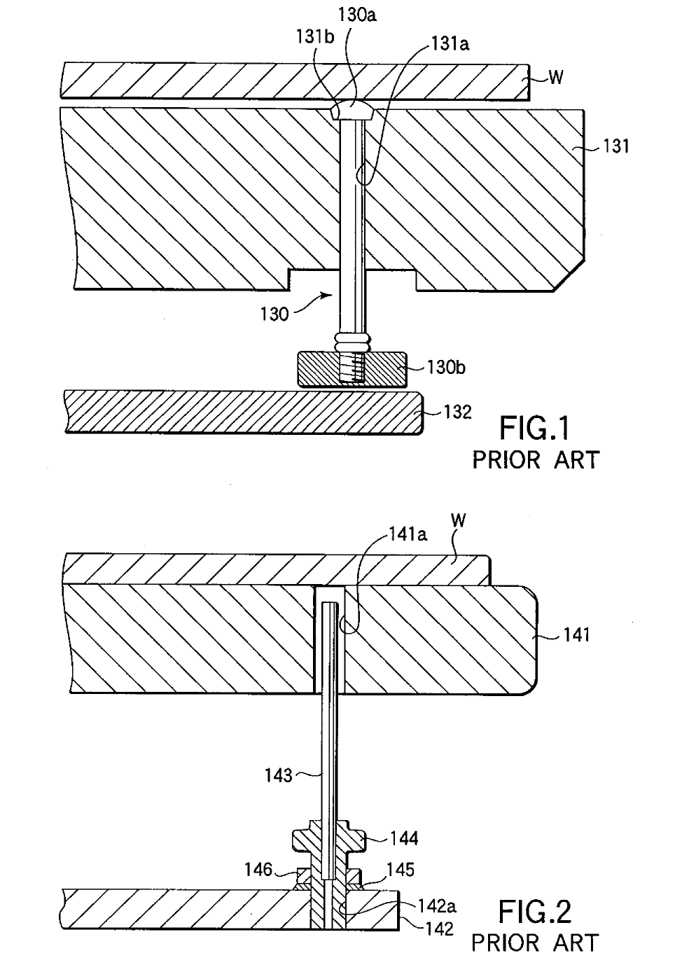

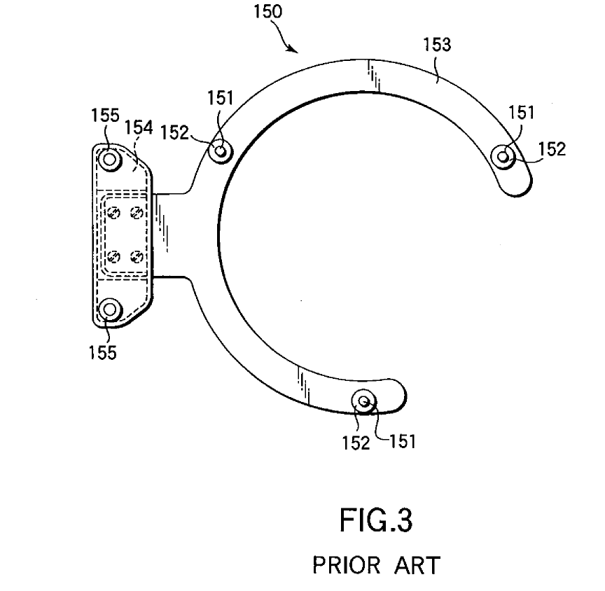

### DETAILED DESCRIPTION OF THE INVENTION

Embodiment of the present invention will now be described with reference to the accompanying drawings.

Hereinafter, an explanation will be given of a case where the present invention is applied to a plasma processing apparatus of the microwave type.

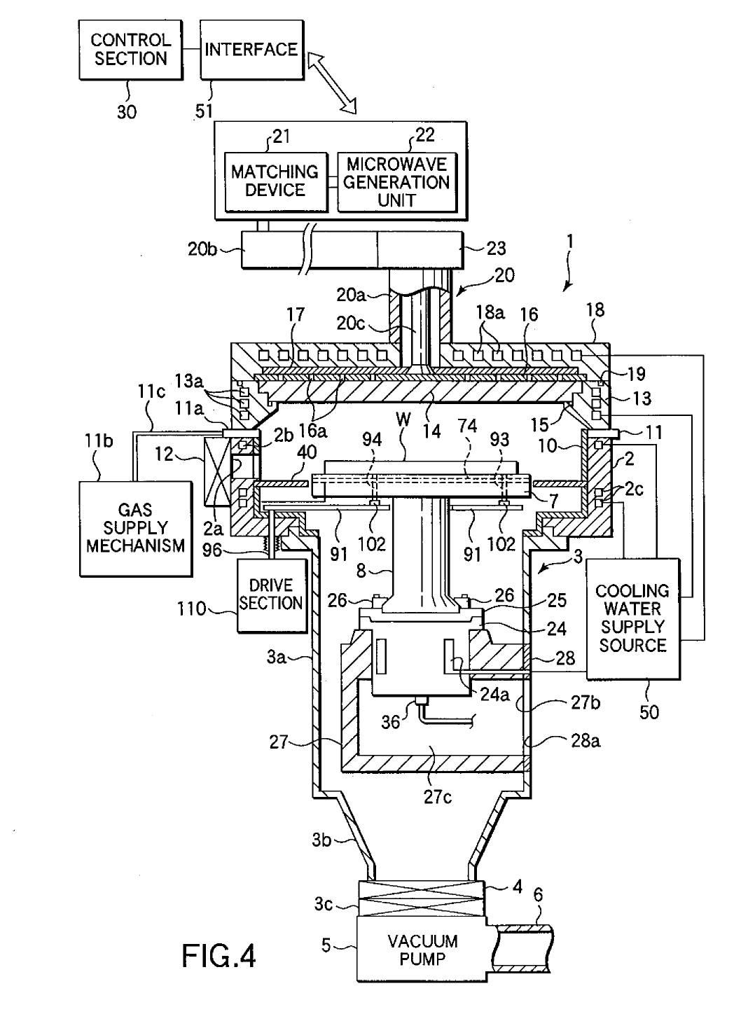

FIG. 4 is sectional view showing a plasma processing apparatus of the microwave type provided with a lifter according to the present invention. This plasma processing apparatus 1 of the microwave type includes an airtight chamber 2, which is formed of an essentially circular cylinder. The essentially circular cylinder of the chamber 2 is made of a metal, such as Al. The bottom of the chamber 2 has an opening portion at the center, and an exhaust pipe 3 is formed continuously to the bottom. The exhaust pipe 3 comprises an upper exhaust pipe 3a having essentially the same diameter as the opening portion, a pipe 3b with a diameter gradually decreasing downward, and an exhaust control valve 3c connected to the pipe 3b through a switching valve 4. The lower end of the exhaust control valve 3c is connected to a vacuum pump 5, which has a side connected to an exhaust duct 6. When the vacuum pump 5 is operated, the interior of the chamber 2 is exhausted through the exhaust pipe 3, and the pressure inside the chamber 2 is decreased to a predetermined vacuum level.

At the center of the chamber 2, a substrate table 7 is disposed to hold a target substrate or semiconductor wafer W thereon in a horizontal state. The substrate table 7 is supported by a support portion 8 made of quartz and extending downward in the vertical direction from the center of the bottom of the substrate table 7 through the opening portion. For example, the substrate table 7 is provided with a heating element 74 made of SiC, an electrode (not shown) made of SiC, and a thermo couple 36, all of which are built therein. When the heating element 74 is supplied with a electric power and thereby emits heat (infrared and/or far infrared rays), the semiconductor wafer W is directly heated.

The side of the substrate table 7 is surrounded by an annular baffle plate 40 made of quartz. This quartz preferably consists of high-purity quartz containing no impurity, and more preferably of opaque quartz. The baffle plate 40 has a plurality of exhaust holes, and is supported by a support member. The baffle plate 40 allows the interior of the chamber 2 to be uniformly exhausted, and prevents contaminants from flowing backward from below due to microwave plasma generated inside the chamber 2.

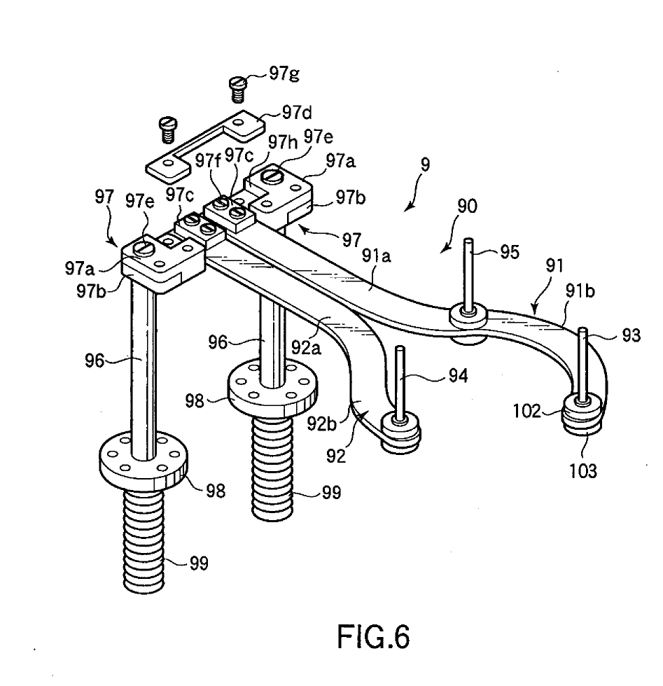

A lifter 9 (see FIG. 6) is arranged below the substrate table 7. The substrate table 7 has three pin insertion holes (only two of them are shown in FIG. 4) formed therethrough in the vertical direction. Pins 93 and 94 made of, e.g., quartz are inserted to be movable up and down in two of the pin insertion holes, and are supported by lifter arm parts 91 and 92 made of, e.g., quartz. The lifter arm parts 91 and 92 and pins 93 and 94 may be made of a ceramic, such as Al₂O₃ or AlN. The lifter arm parts 91 and 92 are arranged to be moved up and down by elevating shafts 96 and 96, which penetrate the bottom of the chamber 2 and are movable up and down. Along with movement of the lifter arm parts 91 and 92, the pins 93 and 94 are moved in the vertical direction, so the semiconductor wafer W is moved up and down.

The chamber 2 is provided with a liner 10 made of opaque quartz and formed of a essentially circular cylinder, which is disposed along the internal surface of the chamber 2. The chamber 2 is opened at the top, and an annular gas feed portion 11 is attached to this opened end surface of the chamber 2. The gas feed portion 11 includes a number of gas discharge holes 11a uniformly formed on the inner side. The gas feed portion 11 is connected to a gas supply mechanism 11b through a line 11c. For example, the gas supply mechanism 11b includes an Ar gas supply source, an O₂ gas supply source, an H₂ gas supply source, an N₂ gas supply source, and other gas supply sources. Each of these gases is supplied into the gas feed portion 11, and is uniformly delivered from the gas discharge holes of the gas feed portion 11 into the chamber 2. In place of Ar gas, another rare gas, such as Kr, He, Ne, or Xe gas, may be used.

The chamber 2 has a transfer port 2a formed in the sidewall, through which the semiconductor wafer W is transferred from a transfer chamber (not shown), which is located adjacent to the plasma processing apparatus 1 of the microwave type, into the chamber 2, and from the chamber 2 into the transfer chamber. The transfer port 2a is opened and closed by a gate valve 12. A cooling water passage 2b is formed in the chamber 2 in an annular direction above the transfer port 2a and is used to allow cooling water to flow therethrough. Another cooling water passage 2c is formed below the transfer port 2a. Cooling water is supplied from a cooling water supply source 50 into the cooling water passages 2a and 2c.

A transmission plate support portion 13 is disposed above the chamber 2, and projects inside the chamber 2. The transmission plate support portion 13 has a plurality of cooling water passages 13a formed therein in an annular direction and used to allow cooling water to flow therethrough. Cooling water is supplied from the cooling water supply source 50 into the cooling water passages 13a. The transmission plate support portion 13 has, e.g., two shoulder portions on the inner side, on which a microwave transmission plate 14 made of a dielectric material, such as quartz, for transmitting microwaves is airtightly fitted by a seal member 15, such as an O-ring. The dielectric material may be made of a ceramic, such as Al₂O₃.

A circular planar antenna 16 is disposed above the microwave transmission plate 14, and is grounded through the transmission plate support portion 13. The planar antenna 16 is formed of a circular copper plate with the surface plated with gold or silver, and is formed to have, e.g., a diameter of 300 to 400 mm and a thickness of 0.1 to 10 mm (for example, 5 mm) for 8-inch wafers W. The planar antenna 16 has a number of microwave radiation holes (slots) 16a formed therethrough in the vertical direction and arrayed in a predetermined pattern. The microwave radiation holes 16a, each of which has a shape of a long groove in the plan view, are arranged such that adjacent microwave radiation holes 16a form a T-shape, and T-shapes are arrayed on a plurality of concentric circles. The intervals of the microwave radiation holes 16a are set to be, e.g., λg/4, λg/2, or λg relative to the wavelength (λg) of microwaves. The planar antenna 16 may be rectangular.

A retardation plate 17 is disposed above the planar antenna 16, and is set to have a diameter slightly smaller than the planar antenna 16. The wave-delaying plate 17 is made of, e.g., quartz, polytetrafluoroethylene, or polyimide, which has a dielectric constant larger than that of vacuum. The wavelength of microwaves becomes longer in a vacuum condition. Accordingly, the retardation plate 17 shortens the wavelength of microwaves to adjust plasma, when microwaves are transmitted in a direction along the diameter (radial direction).

A conductive lid member 18 is disposed above the transmission plate support portion 13 to cover the upper surface and side surface of the reatardation plate 17 and the side surface of the planar antenna 16. The portion between the support portion 13 and lid member 18 is airtightly sealed by a ring-like seal member 19. A cooling water passage 18a is formed in the lid member 18 in an annular direction and is used to allow cooling water to flow therethrough. Cooling water is supplied from the cooling water supply source 50 into the cooling water passage 18a. Consequently the lid member 18, retardation plate 17, planar antenna 16, and microwave transmission plate 14 are cooled, so that plasma is stably generated, and they are prevented from being damaged or deformed.

The lid member 18 has an opening portion formed at the center and connected to a coaxial wave guide tube 20. The coaxial wave guide tube 20 is connected to a microwave generation unit 22 at one end through a matching device 21. The microwave generation unit 22 generates microwaves with a frequency of, e.g., 2.45 GHz, which are transmitted through the coaxial wave guide tube 20 to the planar antenna 16. The microwaves may have a frequency of 8.35 GHz or 1.98 GHz.

The coaxial wave guide tube 20 includes a circular wave guide tube 20a having an outer conductor and extending upward from the opening portion of the lid member 18, and a rectangular coaxial wave guide tube 20b connected to the upper end of the circular wave guide tube 20a through a mode transducer 23 and extending in a horizontal direction. Microwaves are propagated in a TE mode through the rectangular coaxially wave guide tube 20b, and are then transduced from the TE mode into a TEM mode by the mode transducer 23. An inner conductor 20c is provided in the circular wave guide tube 20a at the center to constitute the coaxial wave guide tube 20, in cooperation with the circular wave guide tube 20a. The lower end of the inner conductor 20c passes through a hole formed at the center of the retarding plate 17, and is connected to the planar antenna 16. Microwaves are efficiently propagated through the coaxial wave guide tube 20 to the planar antenna 16 uniformly in the radial direction.

The circular cylindrical support portion 8 for supporting the substrate table 7 is fixed at the bottom to a support portion fixing member 24 by a clamp 26 through a fixing plate 25 made of, e.g., Al. For example, the support portion fixing member 24 is made of Al, and is formed of a circular column having a flange portion. The support portion fixing member 24 is fitted in the upper portion of a fixing member mount component 27 made of Al. A cooling water passage 24a is formed in an annular direction in a side of the support portion fixing member 24 and is used to allow cooling water to flow therethrough. Cooling water is supplied from the cooling water supply source 50 into the cooling water passage 24a. The fixing member mount component 27 is attached to the upper exhaust drum 3a at one side.

The fixing member mount component 27 has an opening portion 27b on the side attached to the upper exhaust pipe 3a. The fixing member mount component 27 is fixed to the upper exhaust pipe 3a in a state where the opening portion 27b is aligned with a hole 28a formed in the upper exhaust pipe 3a. Accordingly, a space portion 27c formed in the fixing member mount component 27 communicates with the outside atmosphere through the opening portion 27b and hole 28a. The space portion 27c contains therein the wiring lines of the thermo couple 36 for measuring the temperature of the substrate table 7, and the wiring lines for supplying an electric power to the heating element 74, and so forth.

The respective components of the plasma processing apparatus 1 of the microwave type are connected through an interface 51 to and controlled by a control section 30 comprising a CPU. Under the control of the control section 30, a predetermined process is performed in the plasma processing apparatus of the microwave type.

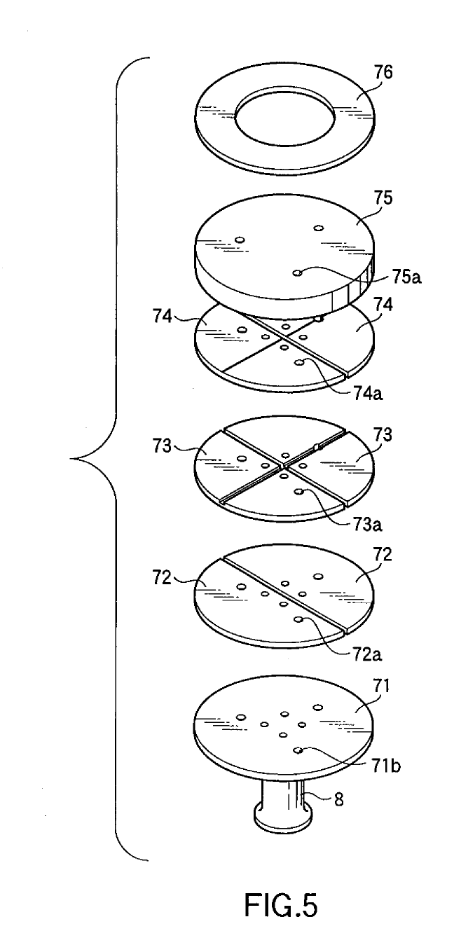

FIG. 5 is an exploded perspective view showing the substrate table 7 and support portion 8. The substrate table 7 includes a circular plate-like base portion 71 made of quartz, on which a first reflector 72 made of Si, an insulating plate 73 made of quartz, and a heating element 74 formed of a conductive SiC sintered body are laminated in this order. The upper surface of the heating element 74 and the side surfaces of the heating element 74, reflector 72, and insulating plate 73 are covered with a cover 75 made of quartz. A second reflector 76 made of Si and formed of a ring is disposed above the cover 75. Each of the first reflector 72, insulating plate 73, and heating element 74 is formed of two semi-circular plates, which are set to abut on each other to form a circular shape for laminating.

FIG. 6 is a perspective view showing the lifter 9. The lifter 9 includes a lifter arm 90 made of quartz and having a pair of arm parts 91 and 92, and is located below the substrate seat member 7. The arm parts 91 and 92 of the lifter 90 are arranged to be moved up and down inside the chamber 2 by the elevating shafts 96, respectively, which penetrate the bottom of the chamber 2 and are movable up and down (see FIG. 4).

The arm parts 91 and 92 are respectively connected to the elevating shafts 96 through coupling portions 97. The arm parts 91 and 92 include extending portions 91a and 92a that extend in a direction aligned with a radial direction of the chamber 2, and circular arc portions 91b and 92b that form a circular arc coaxial with the substrate seat member 7 and having a diameter slightly smaller than that of the substrate seat member 7. The circular arc portion 91b is longer than the circular arc portion 92b. A pin 93 made of quartz stands at the end portion of the circular arc portion 91b, and a pin 95 stands at a position separated by 120° from the pin 93 in an annular direction. A pin 94 stands at the end portion of the circular arc portion 92b. The pins 98, 94, and 95 are separated by 120° from each other in an annular direction.

The coupling portions 97 include two sets of a support plate 97a, a coupling plate 97b, and a stopper plate 97c, as well as a cover 97d and a plurality of screws 97e, 97f, and 97g. The arm parts 91 and 92 for constituting the lifter arm 90 are respectively fixed to the support plates 97a through the stopper plates 97c by the screws 97f. The coupling plates 97b are respectively connected below the ends of the support plates 97a. The screws 97e penetrate the support plates 97a and coupling plates 97b and are fixedly screwed into the upper ends of the elevating shafts 96, respectively.

After the two support plates 97a are set in position, the opposite ends of the cover 97d are fitted in recesses 97h of the coupling plates 97a. The cover 97d is fixed to the support plates 97a by the screws 97g while it covers the backside of the support plates 97a, so that the support plates 97a are coupled to each other.

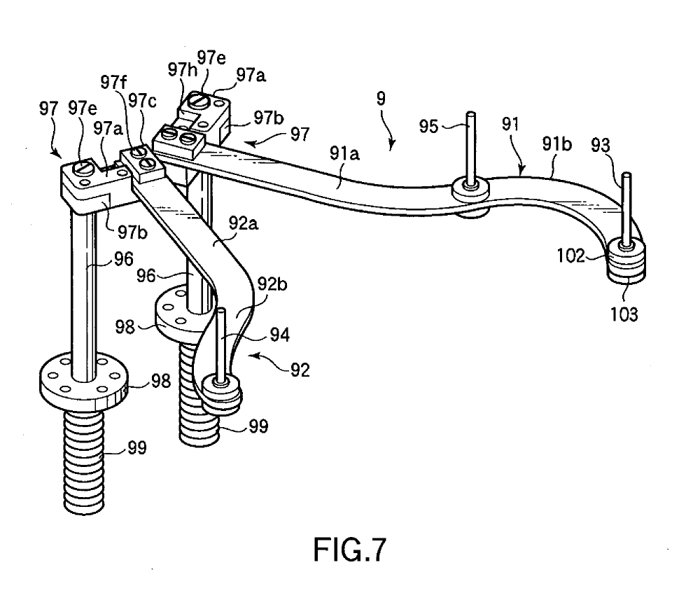

FIG. 7 is a perspective view of the lifter 9 in a state where the arm parts 91 and 92 are unfurled.

When the arm parts 91 and 92 for constituting the lifter arm 90 are unfurled, the screws 97g are loosened and the cover 97d is detached. Then, the fixing screws 97e are loosened to unlock the screw-fixing of the support plate 97a and coupling plate 97b coupled to the arm part 91, and the screw-fixing of the support plate 97a and coupling plate 97b coupled to the arm part 92. Consequently, the arm parts 91 and 92 can be rotated relative to the elevating shafts 96, and thus the arm parts 91 and 92 can be separated from each other, i.e., unfurled, by hand.

The arm parts 91 and 92 may be arranged to be unfurled by a drive section 110 that rotates the elevating shafts 96, as described later.

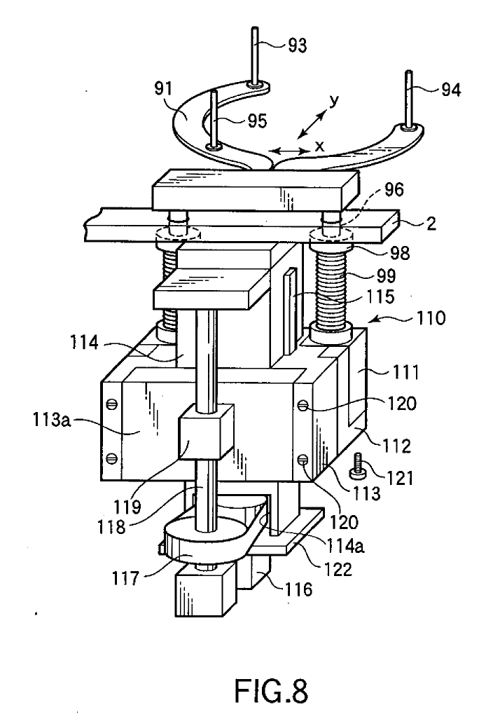

FIG. 8 is a perspective back view of the lifter 9.

The drive section 110 of the lifter 9 includes shaft holders 111, support portions 112, a support portion 113, a column portion 114, linear slide rails 115, a motor 116, a pulley 117, a ball-screw 118, a support portion 119, and a table 122.

The shaft holders 111, support portion 112, and support portion 113 are coupled to each other. The support portion 119 is coupled to a support portion 113a fitted in the support portion 113.

The linear slide rails 115 are formed on the column portion 114 to extend in the vertical direction, and engage with grooves formed in the support portion 113 to extend in the vertical direction. The column portion 114 is mounted on the table 122 above the motor 116. A recess 114a is formed in the column portion 114 on the lower side, and rotation of the motor 116 is transmitted to the pulley 117 through a mechanism disposed inside the recess 114a.

Each of the elevating shafts 96 penetrates the coupling plate 98, extends through an accordion or bellows 99 made of a metal, and is connected to the corresponding shaft holder 111.

When the motor 116 is operated and the ball-screw 118 is rotated by the motor 116 through the pulley 117, the support portion 119 is thereby moved up and down. In conjunction with this, the support portion 113 and the support portions 112 and shaft holders 111 connected thereto are slid up and down along the linear slide rails 115. Consequently, the elevating shafts 96 and 96 are moved up and down, and thus the arm parts 91 and 92 are moved up and down, while the bellows 99 ensures that the interior of the chamber 2 is airtight.

The positions of the elevating shafts 96 and lifter arm parts 91 and 92 coupled thereto can be fine-adjusted in a y-axis direction by rotating screws 120. Further, the positions of the elevating shafts 96 and lifter arm parts 91 and 92 coupled thereto can be fine-adjusted in an x-axis direction by rotating screws 121 that penetrate the bottom of the shaft holders 111 and support portions 112.

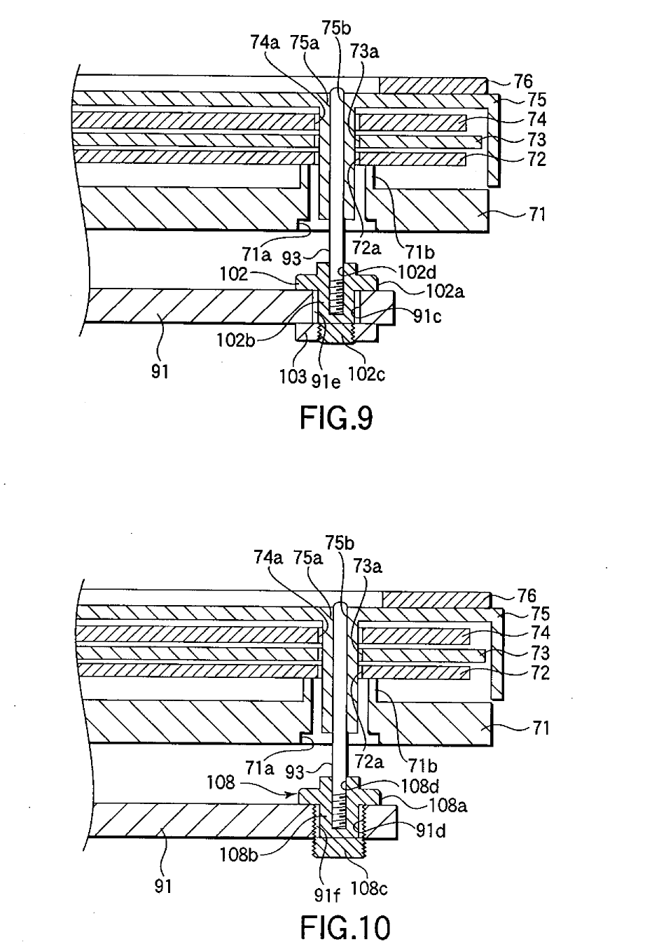

FIG. 9 is a sectional view of the lifter 9 in a state where a pin 93 is inserted into a pin insertion hole formed in the substrate table 7. Pin insertion holes 71a are formed through the base portion 71 in the vertical direction at positions near the peripheral edge of the base portion 71. For example, each of the pin insertion holes 71a is provided with a pipe-like projecting portion 71b extending from the outer edge of the upper hole portion. The first reflector 72 is supported on the top ends of the projecting portions 71b. Similarly, the first reflector 72, insulating plate 73, and heating element 74 have pin insertion holes 72a, pin insertion holes 73a, and pin insertion holes 74a respectively formed therein. Pin insertion portions 75a extend downward in the vertical direction from the bottom of the cover 75, each extending through the pin insertion hole 74a, pin insertion hole 73a, and pin insertion hole 72a, into the pin insertion hole 71a. Each of the pin insertion portions 75a has an insertion hole 75b for, e.g., the pin 93 to be movable up and down.

The arm part 91 has a through-hole 91c formed therethrough at the end portion. A pin fixing portion 102 for supporting the pin 93 is inserted into the through-hole 91c formed in the arm part 91, and is fixed to the arm part 91 at the bottom by a lower fixing portion 103. The pin fixing portion 102 is formed of, e.g., a nut, which includes a flange portion 102a, a movable portion 102b, a screw portion 102c, and a pin insertion hole 102d. The flange portion 102a has a diameter larger than the movable portion 102b. The lower end of the pin 93 is fixedly screwed into the pin insertion hole 102d. The movable portion 102b is inserted with some allowance in the through-hole 91c. The flange portion 102a has a diameter larger than the through-hole 91c, and is thereby set in contact with the upper surface of the arm part 91. The screw portion 102c has a male screw on the outer surface. The lower fixing portion 103 formed of a fixing member, such as a nut, has a diameter larger than the through-hole 191c. The lower fixing portion 103 is screwed on the screw portion 102c, and is set in contact with the lower surface of the arm part 91. In this state, the pin fixing portion 102 can be moved along with the pin 93, back and forth and right and left.

Similarly, each of the other pins 94 and 95 is also fixedly screwed into the corresponding pin fixing portion 102, and the movable portion 102b of this pin fixing portion 102 is inserted with some allowance in the corresponding one of the through-holes 91c formed in the arm parts 91 and 92. The space 91e is created between the arm part 91 and the movable portion 102b.

As described above, when the arm parts 91 and 92 are moved up and down by the elevating shafts 96 and 96, the pins 93, 94, and 95 supported by the arm parts 91 and 92 are moved up and down. When the pins 93, 94, and 95 are moved up and their upper ends project from the substrate table 7, the semiconductor wafer W is lifted. On the other hand, when the pins 93, 94, and 95 are moved down and their upper ends retreat into the substrate table 7, the semiconductor wafer W is placed on the substrate table 7.

Since the pin fixing portion 102 is inserted with some allowance in the through-hole 91c, the pin fixing portion 102 screwed on the pin 93 can be moved in the radial direction of the through-hole 91c by that much corresponding to the allowance. Accordingly, when the lifter 9 is assembled in the chamber 2, the pin 93 can be easily inserted into the pin insertion portion 75a and easily guided into the pin insertion hole 75b.

At this time, even if the pin 93 comes into contact with the inner wall of the pin insertion hole 75b, the central axis of the pin 93 can be immediately aligned with the central axis of the pin insertion hole 75b during insertion, because the pin fixing portion 102 is a floating state. When the substrate table 7 is thermally expanded during a process, the pin 93 can be smoothly moved up and down through the pin insertion hole 75b without being damaged, because the pin 93 is freely movable within the through-hole 91c. Accordingly, the diameter of the pin 93 can be set larger than that of conventional pins, so that the semiconductor wafer W can be more stably supported and transferred.

Similarly, each of the other pins 94 and 95 can be easily inserted into the corresponding pin insertion hole and pin insertion portion. Further, the setting of each of the pins 94 and 95 can be easily adjusted relative to the corresponding pin insertion hole and pin insertion portion. Consequently, the pins 94 and 95 are prevented from be damaged.

It is assumed that the support portion fixing member 24 fixed to the support portion 8 with the substrate table 7 connected thereto is attached inside the chamber 2 and exhaust drum 3 after the lifter 9 is attached to the chamber 2. In this case, according to this embodiment, if the outer diameter of the support portion fixing member 24 is larger than the inner diameter of the circle formed by the arm parts 91 and 92, the arm parts 91 and 92 for constituting the lifter arm 90 can be separated from each other, i.e., unfurled. Accordingly, the support portion fixing member 24 can be carried through the arm parts 91 and 92 from above, and fitted in the fixing member mount component 27, so that it is fixed to the exhaust pipe 3. Further, the arm parts 91 and 92 can be replaced with other arm parts in a state where the support portion fixing member 24 is attached to the chamber 2. In this case, the arm parts 91 and 92 are spread right and left and the screws 97f are unlocked, so that the arm parts 91 and 92 can be detached from the support plates 97a and 97a.

Accordingly, this embodiment allows a maintenance operation to be performed in a shorter time.

Further, since the arm parts 91 and 92 are separate each other, the heights of the arm parts 91 and 92 can be individually adjusted by use of adjusting screws. Accordingly, if the heights of the pins 93 and 95 and the pin 94 are misaligned due to a difference in dimensional accuracy of the arm parts 91 and 92, the heights can be adjusted for alignment.

According to the plasma processing apparatus 1 of the microwave type arranged as described above, for example, Ar gas and O₂ gas are supplied from the gas feed portion 11, while microwaves of a predetermined frequency are applied from the planar antenna 16, so that high density plasma is generated within the chamber 2. Ar gas plasma thus excited acts on oxygen molecules and thereby efficiently and uniformly generates oxygen radicals within the chamber 2, by which the surface of a semiconductor wafer W placed on the substrate seat member 7 is oxidized. Where a nitridation process is performed on a semiconductor wafer W, a rare gas, such as Ar gas, and NH₃ gas or N₂ gas are supplied from the gas feed portion 11 into the chamber 2. Where an oxynitridation process is performed on a semiconductor wafer W, O₂ gas may be supplied in addition to the gasses used for the nitridation process.

In this plasma processing apparatus 1 of the microwave type, when the lifter arm parts 91 and 92 are moved down, the pins 93, 94, and 95 are pulled down by the flange portions 102a of the pin fixing portions 102, so that the pins 93, 94, and 95 are smoothly and easily separated from the semiconductor wafer W. Consequently, the pins 93, 94, and 95 are prevented from sticking to the semiconductor wafer W by an electrostatic force, and thus from causing a transfer error of the semiconductor wafer W.

FIG. 10 is a sectional view showing another lifter according to another embodiment of the present invention in a state where a pin is inserted into a pin insertion hole formed in a substrate seat member. In FIG. 10, the same constituent elements as those of the pin 93 and substrate seat member 7 shown FIG. 9 are denoted by the same reference numerals.

An arm part 91 used for constituting the lifter arm 90 has a screw hole 91d formed therethrough at the end portion. A pin fixing portion 108, which includes a flange portion (support portion) 108a, a movable portion 108b, a lower fixing portion 108c, and a pin insertion hole 108d, is inserted into the screw hole 91d. The flange portion 108a has a diameter larger than the movable portion 108b. The lower end of the pin 93 is fixedly screwed into the pin insertion hole 108d. The movable portion 108b is inserted with some allowance in the screw hole 91d. The flange portion 108a has a diameter larger than the screw hole 91d, and is thereby set in contact with the upper surface of the arm part 91. The lower fixing portion 108c has a male screw on the outer surface to be screwed into the screw hole 91d. The lower fixing portion 108c supports the movable portion 108b from below, while it projects downward from the screw hole 91d, when the male screw is screwed into the screw hole 91d. An annular gap 91f is formed between the screw hole 91d and movable portion 108b. In this state, the pin fixing portion 108 can be moved along with the pin 93, back and forth and right and left.

Similarly, each of the other pins 94 and 95 is also fixedly screwed into the corresponding pin fixing portion 108, and the movable portion 108b of this pin fixing portion 108 is inserted with some allowance in the corresponding one of the screw holes formed in the arm parts 91 and 92.

Since the pin fixing portion 108 is inserted with some allowance in the screw hole 91d, the pin fixing portion 108 screwed on the pin 93 can be moved in the radial direction of the screw hole 91d by that much corresponding to the allowance. Accordingly, when the lifter 9 is assembled in the chamber 2, the pin 93 can be easily inserted into the pin insertion portion 75a and easily guided into the pin insertion hole 75b.

At this time, even if the pin 93 comes into contact with the inner wall of the pin insertion hole 75b, the central axis of the pin 93 can be immediately aligned with the central axis of the pin insertion hole 75b during insertion, because the pin fixing portion 108 is a floating state. When the substrate seat member 7 is thermally expanded during a process, the pin 93 can be smoothly moved up and down through the pin insertion hole 75b without being damaged, because the pin 93 is freely movable within the screw hole 91d. Accordingly, the diameter of the pin 93 can be set larger than that of conventional pins, so that the semiconductor wafer W can be more stably supported and transferred.

Similarly, each of the other pins 94 and 95 can be easily inserted into the corresponding pin insertion hole and pin insertion portion. Further, the setting of each of the pins 94 and 95 can be easily adjusted relative to the corresponding pin insertion hole and pin insertion portion. Consequently, the pins 94 and 95 are prevented from be damaged.

In this plasma processing apparatus 1 of the microwave type, when the lifter arm part 91 is moved down, the pin 93 is pulled down by the flange portion 108a, so that the pin 93 is smoothly and easily separated from the semiconductor wafer W. Consequently, the pin is prevented from sticking to the semiconductor wafer W, and thus from causing a transfer error of the semiconductor wafer W.

Further, since the pin fixing portion 108 is integrally formed, the lower fixing portion 108c does not cause a positional shift when the lifter arm part 91 is moved up and down. Accordingly, the pin fixing portion 108 is stably fixed to the lifter arm part 91.

Similarly, each of the other pins 94 and 95 is smoothly and easily separated from the semiconductor wafer W, and is prevented from causing a transfer error of the semiconductor wafer W.

The present invention is not limited to the embodiments described above, and it may be modified in various manners. For example, in the embodiments described above, the structure of the plasma processing apparatus 1 of the microwave type, including the elevating mechanism for the lifter 9 and the inner structure of the substrate seat member 7, is not limited to that shown in the embodiments.

In the embodiments described above, the present invention is applied to a plasma processing apparatus of the microwave type, but the present invention may be applied to another plasma processing apparatus, such as a plasma processing apparatus of the parallel-plate type or a plasma processing apparatus of the inductive coupling type. Further, in the embodiments described above, the present invention is applied to a plasma processing apparatus, but the present invention may be applied to an apparatus other than a plasma processing apparatus. Furthermore, in the embodiments described above, the present invention is exemplified by an oxidation process, nitridation process, or oxynitridation process, but this is not limiting. For example, the present invention may be applied to an apparatus for performing another process, such as a film formation process, etching process, heating process, reformation process, or crystallization process.

What is claimed is:

1. A lifter comprising:
a plurality of pins inserted in a plurality of holes formed through a table for placing thereon a target object to be processed, the plurality of pins being configured to support;
a lifter arm configured to support the plurality of pins; and
pin fixing portions configured to respectively fix the pins to the lifter arm,
such that the pins are moved up and down by the lifter arm and thereby caused to project and retreat relative to the holes of the table so as to move up and down the target object,
wherein each of the pin fixing portions is inserted into a through-hole formed in the lifter arm, and comprises
a movable portion having a pin insertion hole formed therein to fix a corresponding one of the pins, the movable portion being inserted in the through-hole with a gap formed therebetween,
a support portion connected to the movable portion on an upper side and having a diameter larger than that of the movable portion, the support portion being set in contact with an upper surface of the lifter arm while said one of the pins extending therethrough,
an engage portion connected to the movable portion on a lower side and projecting downward from the through-hole, and
a stopper portion engaged with engage portion and set in contact with a lower surface of the lifter arm,
such that the pin fixing portion is allowed to move in a horizontal direction by the gap around the movable portion.

2. A lifter comprising:
a plurality of pins inserted in a plurality of holes formed through a table for placing thereon a target object to be processed, the plurality of pins being configured to support;
a lifter arm configured to support and move up and down the plurality of pins; and
pin fixing portions configured to respectively fix the pins to the lifter arm,
such that the pins are moved up and down by the lifter arm and thereby caused to project and retreat relative to the holes of the table so as to move up and down the target object,
wherein each of the pin fixing portions is inserted into a screw hole formed in the lifter arm and having a screw on an inner wall, and comprises
a movable portion having a pin insertion hole formed therein to fix a corresponding one of the pins, the movable portion being inserted in the screw hole with a gap formed therebetween,
a support portion connected to the movable portion on an upper side and having a diameter larger than that of the movable portion, the support portion being set in contact with an upper surface of the lifter arm while said one of the pins extending therethrough, and
a stopper portion connected to the movable portion on a lower side and having a male screw formed on an outer surface to be screwed into the screw hole, the stopper portion supporting the movable portion from below while the male screw being screwed into the screw hole and projecting downward from the screw hole,
such that the pin fixing portion is allowed to move in a horizontal direction by the gap around the movable portion.

3. A processing apparatus comprising:
a chamber configured to accommodate a target object;
a table configured to place thereon the target object inside the chamber;
a process mechanism configured to perform a predetermined process on the target object inside the chamber;
a lifter configured to move up and down the target object above the table; and
a driving mechanism for driving the lifter,
wherein the lifter comprises a plurality of pins configured to support and move up and down the target object above the table, a lifter arm configured to support and move up and down the plurality of pins, and pin fixing portions configured to respectively fix the pins to the lifter arm,
the table has a plurality of holes formed therethrough in which the pins are inserted, such that the pins are moved up and down by the lifter arm and thereby caused to project and retreat relative to the holes so as to move up and down the target object, and
each of the pin fixing portions is inserted into a through-hole formed in the lifter arm, and comprises
a movable portion having a pin insertion hole formed therein to fix a corresponding one of the pins, the movable portion being inserted in the through-hole with a gap formed therebetween,
a support portion connected to the movable portion on an upper side and having a diameter larger than that of the movable portion, the support portion being set in contact with an upper surface of the lifter arm while said one of the pins extending therethrough,
an engage portion connected to the movable portion on a lower side and projecting downward from the through-hole, and
a contact portion engaged with engage portion and set in contact with a lower surface of the lifter arm,
such that the pin fixing portion is allowed to move in a horizontal direction by the gap around the movable portion.

4. A processing apparatus comprising:
a chamber configured to accommodate a target object;
a table configured to place thereon the target object inside the chamber;
a process mechanism configured to perform a predetermined process on the target object inside the chamber:
a lifter configured to move up and down the target object above the table; and
a driving mechanism for driving the lifter,
wherein the lifter comprises a plurality of pins configured to support and move up and down the target object above the table, a lifter arm configured to support and move up and down the plurality of pins, and pin fixing portions configured to respectively fix the pins to the lifter arm,
the table has a plurality of holes formed therethrough in which the pins are inserted, such that the pins are moved up and down by the lifter arm and thereby caused to project and retreat relative to the holes so as to move up and down the target object, and
each of the pin fixing portions is inserted into a screw hole formed in the lifter arm and having a screw on an inner wall, and comprises
a movable portion having a pin insertion hole formed therein to fix a corresponding one of the pins, the movable portion being inserted in the screw hole with a gap formed therebetween,
a support portion connected to the movable portion on an upper side and having a diameter larger than that of the movable portion, the support portion being set in contact with an upper surface of the lifter arm while said one of the pins extending therethrough, and
a stopper portion connected to the movable portion on a lower side and having a male screw formed on an outer surface to be screwed into the screw hole, the stopper portion supporting the movable portion from below while the male screw being screwed into the screw hole and projecting downward from the screw hole,
such that the pin fixing portion is allowed to move in a horizontal direction by the gap around the movable portion.

5. A lifter comprising:
a plurality of pins inserted in a plurality of holes formed through a table for placing thereon a target object to be processed, the plurality of pins being configured to support;
a lifter arm configured to support the plurality of pins;
a support portion configured to horizontally support the lifter arm; and
an elevating section coupled to the support portion and configured to move up and down while horizontally supporting the lifter arm so as to move up and down the lifter arm,
such that the pins are supported and moved up and down by the lifter arm and thereby caused to project and retreat relative to the holes of the table so as to move up and down the target object,
wherein the lifter arm comprises a pair of arm parts,
the support portion comprises a pair of support plates configured to respectively and horizontally support the arm parts,
the elevating section comprises a pair of elevating shafts respectively coupled to the support plates and configured to move up and down while respectively and horizontally supporting the arm parts so as to move up and down the arm parts, and
the arm parts are operated to move up and down in set positions where the arm parts are close to each other, and the arm parts are separable from each other by rotating the elevating shafts or rotating the support plates relative to the elevating shafts from the set positions.

6. The lifter according to claim 5, wherein the arm parts respectively extend from ends of the support plates in a direction perpendicular to a longitudinal direction of the support plates, and other ends of the support plates are respectively fixed to upper ends of the elevating shafts by fixing screws extending therethrough,
the lifter further comprises a coupling plate configured to couple the support plates to each other in a state where ends of the support plates are set to abut on each other, and
coupling by the coupling plate is unlocked, and the fixing screws are loosened, so that the support plates are set to be rotatable relative to the elevating shafts, when the arm parts are separated from each other.

7. The lifter according to claim 5 comprising pin fixing portions configured to respectively fix the pins to the lifter arm,
each of the pin fixing portions being inserted into a through-hole formed in the lifter arm, and comprising
a movable portion having a pin insertion hole formed therein to fix a corresponding one of the pins, the movable portion being inserted in the through-hole with a gap formed therebetween,
a support portion connected to the movable portion on an upper side and having a diameter larger than that of the movable portion, the support portion being set in contact with an upper surface of the lifter arm while said one of the pins extending therethrough,
an engage portion connected to the movable portion on a lower side and projecting downward from the through-hole, and
a contact portion engaged with engage portion and set in contact with a lower surface of the lifter arm,
such that the pin fixing portion is allowed to move in a horizontal direction by the gap around the movable portion.

8. A lifter according to claim 5, further comprising pin fixing portions configured to respectively fix the pins to the lifter arm,
such that the pins are moved up and down by the lifter arm and thereby caused to project and retreat relative to the holes of the table so as to move up and down the target object,
wherein each of the pin fixing portions being inserted into a screw hole formed in the lifter arm and having a screw on an inner wall, and comprising
a movable portion having a pin insertion hole formed therein to fix a corresponding one of the pins, the movable portion being inserted in the screw hole with a gap formed therebetween,
a support portion connected to the movable portion on an upper side and having a diameter larger than that of the movable portion, the support portion being set in contact with an upper surface of the lifter arm while said one of the pins extending therethrough, and
a stopper portion connected to the movable portion on a lower side and having a male screw formed on an outer surface to be screwed into the screw hole, the stopper portion supporting the movable portion from below while the male screw being screwed into the screw hole and projecting downward from the screw hole,
such that the pin fixing portion is allowed to move in a horizontal direction by the gap around the movable portion.

9. A processing apparatus comprising:
a chamber configured to accommodate a target object;
a table configured to place thereon the target object inside the chamber;
a process mechanism configured to perform a predetermined process on the target object inside the chamber;
a lifter configured to move up and down the target object above the table; and
a driving mechanism for driving the lifter,
wherein the lifter comprises a plurality of pins configured to support a lifter arm configured to support the plurality of pins, a support portion configured to horizontally support the lifter arm, and an elevating section coupled to the support portion and configured to move up and down while horizontally supporting the lifter arm so as to move up and down the lifter arm,
the table has a plurality of holes formed therethrough in which the pins are inserted, such that the pins are moved up and down by the lifter arm and thereby caused to project and retreat relative to the holes so as to move up and down the target object,
the lifter arm comprises a pair of arm parts,
the support portion comprises a pair of support plates configured to respectively and horizontally support the arm parts,
the elevating section comprises a pair of elevating shafts respectively coupled to the support plates and configured to move up and down while respectively and horizontally supporting the arm parts so as to move up and down the arm parts, and
the arm parts are operated to move up and down in set positions where the arm parts are close to each other, and the arm parts are separable from each other by rotating the elevating shafts or rotating the support plates relative to the elevating shafts from the set positions.

10. The processing apparatus according to claim 9, wherein the arm parts respectively extend from ends of the support plates in a direction perpendicular to a longitudinal direction of the support plates, and other ends of the support plates are respectively fixed to upper ends of the elevating shafts by fixing screws extending therethrough,
the lifter further comprises a coupling plate configured to couple the support plates to each other in a state where ends of the support plates are set to abut on each other, and
coupling by the coupling plate is unlocked, and the fixing screws are loosened, so that the support plates are set to be rotatable relative to the elevating shafts, when the arm parts are separated from each other.

11. A processing apparatus according to claim 9, wherein the lifter further comprises pin fixing portions configured to respectively fix the pins to the lifter arm,
each of the pin fixing portions being inserted into a through-hole formed in the lifter arm, and comprising
a movable portion having a pin insertion hole formed therein to fix a corresponding one of the pins, the movable portion being inserted in the through-hole with a gap formed therebetween,
a support portion connected to the movable portion on an upper side and having a diameter larger than that of the movable portion, the support portion being set in contact with an upper surface of the lifter arm while said one of the pins extending therethrough,
an engage portion connected to the movable portion on a lower side and projecting downward from the through-hole, and
a contact portion engaged with engage portion and set in contact with a lower surface of the lifter arm,
such that the pin fixing portion is allowed to move in a horizontal direction by the gap around the movable portion.

12. A processing apparatus according to claim 9,
wherein the lifter further comprises pin fixing portions configured to respectively fix the pins to the lifter arm,
such that the pins are moved up and down by the lifter arm and thereby caused to project and retreat relative to the holes of the table so as to move up and down the target object,
wherein each of the pin fixing portions being inserted into a screw hole formed in the lifter arm and having a screw on an inner wall, and comprising
a movable portion having a pin insertion hole formed therein to fix a corresponding one of the pins, the movable portion being inserted in the screw hole with a gap formed therebetween,
a support portion connected to the movable portion on an upper side and having a diameter larger than that of the movable portion, the support portion being set in contact with an upper surface of the lifter arm while said one of the pins extending therethrough, and
a stopper portion connected to the movable portion on a lower side and having a male screw formed on an outer surface to be screwed into the screw hole, the stopper portion supporting the movable portion from below while the male screw being screwed into the screw hole and projecting downward from the screw hole,
such that the pin fixing portion is allowed to move in a horizontal direction by the gap around the movable portion.
